(19) United States
(12) Patent Application Publication
(10) Pub. No.: US 2016/0157392 A1
(43) Pub. Date: Jun. 2, 2016

(54) ELECTRONIC DEVICE MODULE HAVING A SHIELD LAYER

(71) Applicant: KABUSHIKI KAISHA TOSHIBA, Tokyo (JP)

(72) Inventor: Akihiko HAPPOYA, Ome Tokyo (JP)

(21) Appl. No.: 14/822,879

(22) Filed: Aug. 10, 2015

(30) Foreign Application Priority Data
Dec. 1, 2014 (JP) 2014-243522

(51) Int. Cl. H05K 9/00

(52) U.S. Cl. CPC H05K 9/0007; H05K 9/0084

(57) ABSTRACT

An electronic device module includes an electronic unit, a sealing layer covering the electronic unit and containing organic molecules, a shield layer covering the sealing layer and containing inorganic elements on an inner surface thereof, and a bonding layer formed between the sealing layer and the shield layer, and containing molecules that are chemically bonded with the organic molecules of the sealing layer and the inorganic elements of the shield layer.

### CROSS-REFERENCE TO RELATED APPLICATION

This application is based upon and claims the benefit of priority from Japanese Patent Application No. 2014-243522, filed Dec. 1, 2014, the entire contents of which are incorporated herein by reference.

### FIELD

Embodiments described herein relate to an electronic device module having a shield layer.

### BACKGROUND

A semiconductor package or module mounted on an electronic device is covered by an electromagnetic shield to shield an electromagnetic wave. For example, a metal layer, which serves as an electromagnetic shield, is formed on a mold resin of the semiconductor package or module by plating or sputtering. However, the shield may increase the size of the semiconductor package or module.

### DESCRIPTION OF THE DRAWINGS

FIG. 1 is a perspective view of an electronic device according to an embodiment.

FIG. 2 is a cross-sectional view of a portion of the electronic device according to the embodiment.

FIG. 3 is an enlarged cross-sectional view of a portion of a semiconductor package according to the embodiment.

FIG. 4 is a flowchart of some steps of a manufacturing method of the semiconductor package according to the embodiment.

FIG. 5 is a cross-sectional view of an electronic component according to the embodiment.

FIG. 6 is a cross-sectional view of the component according to the embodiment on which a film is laminated.

FIG. 7 is a cross-sectional view of a portion of the electronic component according to the embodiment to which a surface treatment is performed.

FIG. 8 is a cross-sectional view of a portion of the electronic component according to the embodiment and a molecular bonding agent to be applied thereto.

FIG. 9 is a cross-sectional view of a portion of the electronic component according to the embodiment with which the molecular bonding agent is chemically bonded.

FIG. 10 is a cross-sectional view of a portion of the electronic component according to the embodiment where catalyst elements are chemically bonded to the molecular bonding agent.

FIG. 11 is a cross-sectional view of the electronic component according to the embodiment on which a shield is formed.

### DETAILED DESCRIPTION

In general, according to an embodiment, an electronic device module includes an electronic unit, a sealing layer covering the electronic unit and containing organic molecules, a shield layer covering the sealing layer and containing inorganic elements on an inner surface thereof, and a bonding layer formed between the sealing layer and the shield layer, and containing molecules that are chemically bonded with the organic molecules of the sealing layer and the inorganic elements of the shield layer.

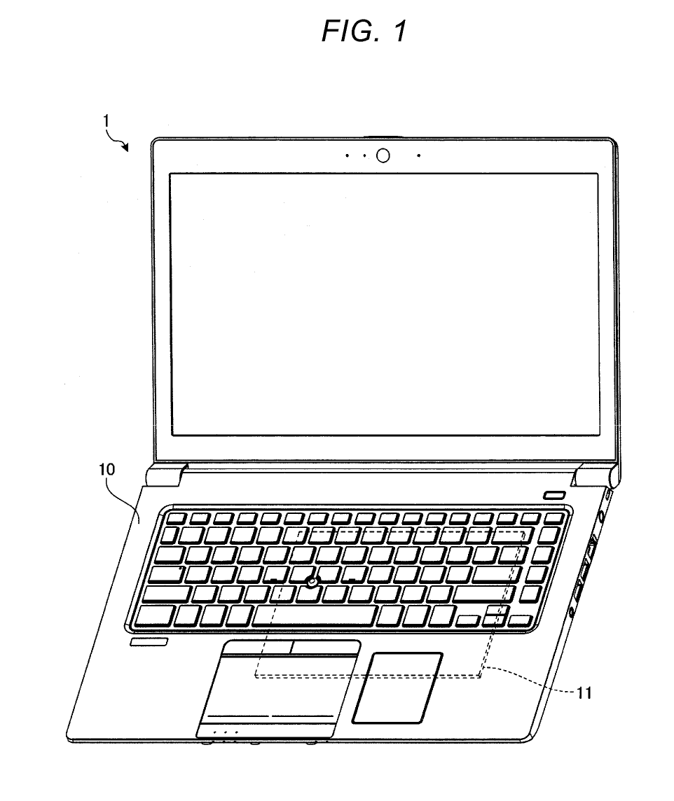

Hereinafter, an embodiment is explained with reference to FIG. 1 to FIG. 11. Structural elements according to the embodiment may be described using a plurality of expressions, and the explanation of these structural elements may be also described using a plurality of expressions. It is also possible to describe these structural elements or the explanation of these structural elements using other expressions not described in this disclosure. Further, other expressions may be also used with respect to the structural elements which are not described using a plurality of expressions and the explanation of these structural elements which are not described using a plurality of expressions.

FIG. 1 is a perspective view of an electronic device 1 according to the embodiment. The electronic device 1 is a personal computer, for example. The electronic device 1 is not limited to the personal computer, and may be other electronic devices such as a portable computer, a tablet, a smart phone, a mobile phone, a personal digital assistant (PDA), a television receiver set, and a display.

As shown in FIG. 1, the electronic device 1 includes a housing 10 and a printed circuit board (PCB) 11. For example, the housing 10 may be referred to as an exterior component or a wall. The PCB 11 is one example of a first substrate, and maybe referred to as a component. The PCB 11 is accommodated in the housing 10, and is depicted by a broken line in FIG. 1.

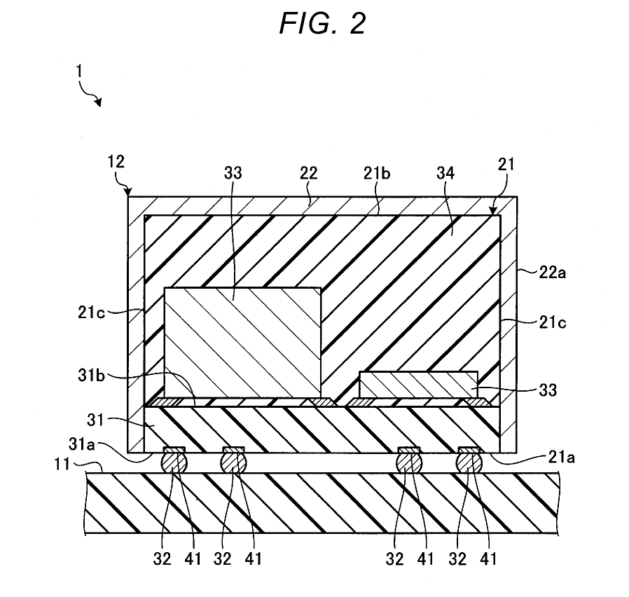

FIG. 2 is a cross-sectional view of a portion of the electronic device 1. As shown in FIG. 2, the electronic device further includes a semiconductor package 12. The semiconductor package 12 maybe referred to as a module, a unit, a component, or an assembled product.

The semiconductor package 12 is a ball grid array (BGA), for example. The semiconductor package 12 is not limited to the BGA, and may be other semiconductor packages. The semiconductor package 12 is mounted on the PCB 11. The semiconductor package 12 may be mounted on other components such as a flexible printed circuit board (FPC), for example.

The semiconductor package 12 includes an electronic component 21 and a shield 22. The electronic component 21 may be referred to as a package, a module, a unit, an assembled product, a mounting component, or an object. The shield 22 is one example of a shield or a conductive portion, and may be referred to as a metal layer, a conductive layer, a layer, a cover portion, a shielding component, a shut-off component, or a portion.

The electronic component 21 is formed in a substantially rectangular parallelepiped shape. The shape of the electronic component 21 is not limited to such a shape. The electronic component 21 has a bottom surface 21a, an upper surface 21b, and a plurality of side surfaces 21c. The bottom surface 21a, the upper surface 21b, and the side surfaces 21c are outer surfaces. The electronic component 21 may have other surfaces as the outer surfaces. The bottom surface 21a is described as a surface on which electrodes are mounted thereon.

The bottom surface 21a is a surface facing the PCB 11. The upper surface 21b is a surface opposite to the bottom surface 21a. The side surfaces 21c are surfaces provided between the bottom surface 21a and the upper surface 21b. The bottom surface 21a, the upper surface 21b, and the side surfaces 21c are formed substantially flat. However, these surfaces may have a curved surface portion or an uneven portion.

The electronic component 21 further includes a substrate 31, a plurality of terminals 32, a plurality of electronic components 33, and a solder resist 34. The substrate 31 is one example of a second substrate, and may be referred to as a component, for example. The terminal 32 may be referred to as a bonding portion, for example. The solder resist 34 is one example of a sealing material, and may be referred to as a mold, a protective portion, a cover portion, a housing portion, or a portion. The electronic component 33 may be referred to as a component or a generation source.

The substrate 31 is a substrate of the semiconductor package 12. The substrate 31 has a bottom surface 31a and a mounting surface 31b. The bottom surface 31a is one example of a first surface, and forms the bottom surface 21a of the electronic component 21. The bottom surface 21a of the electronic component 21 may be formed of other portions. The mounting surface 31b is one example of a second surface, and is a substantially flat surface opposite to the bottom surface 31a.

The substrate 31 further includes a plurality of electrodes 41. Each of the electrodes 41 may be referred to as a bonding portion or a conductive portion. The electrodes 41 are electrodes of the semiconductor package 12. The plurality of electrodes 41 are mounted on the bottom surface 31a of the substrate 31 (the bottom surface 21a of the electronic component 21), respectively.

The plurality of terminals 32 is formed using solder, for example, and is formed into a spherical shape. The material and the shape of the terminal 32 are not limited to such material and shape. Each of the terminals 32 is mounted on corresponding one of the electrodes 41 on the substrate 31. Each terminal 32 electrically connects a land formed on the PCB 11 and the electrode 41 to each other. According to such a configuration, the semiconductor package 12 is mounted on the PCB 11.

The plurality of electronic components 33 are mounted on the mounting surface 31b of the substrate 31, respectively. The plurality of electronic components 33 includes electronic elements, such as capacitors, and semiconductor packages each of which includes various electronic elements, for example. However, the electronic components 33 are not limited to such electronic components. The electronic components 33 may generate (emit) an electromagnetic wave respectively.

The solder resist 34 is made of a synthetic resin such as an epoxy resin, for example. The synthetic resin is one example of an organic material. The solder resist 34 is disposed on the mounting surface 31b of the substrate 31. The solder resist 34 covers the mounting surface 31b and the plurality of electronic components 33, and protects the electronic components 33. In other words, the plurality of electronic components 33 is disposed in the inside of the solder resist 34. The solder resist 34 forms the upper surface 21b of the electronic component 21. The substrate 31 and the solder resist 34 form the side surfaces 21c of the electronic component 21. In other words, the solder resist 34 has the upper surface 21b and portions of the side surfaces 21c as one example of the outer surface.

The shield 22 is a metal layer formed by performing electroless plating on a surface of the electronic component 21 using copper, for example. However, the shield 22 is not limited to such a metal layer, and may be made of other materials having conductivity or may be formed by other methods.

The shield 22 covers the upper surface 21b and the side surfaces 21c of the electronic component 21. That is, the shield 22 covers the outer surfaces of the electronic component 21 other than the bottom surface 21a on which the electrodes 41 are mounted. The shield 22 may also cover a portion of the bottom surface 21a of the electronic component 21. In this case, the shield 22 is apart from the electrodes 41.

The shield 22 reflects and absorbs electromagnetic waves which the electronic components 33 generate, thus attenuating energy of the electromagnetic waves. According to such a function of the shield 22, the shield 22 suppresses electromagnetic waves which the electronic components 33 generate from being radiated to the outside of the semiconductor package 12.

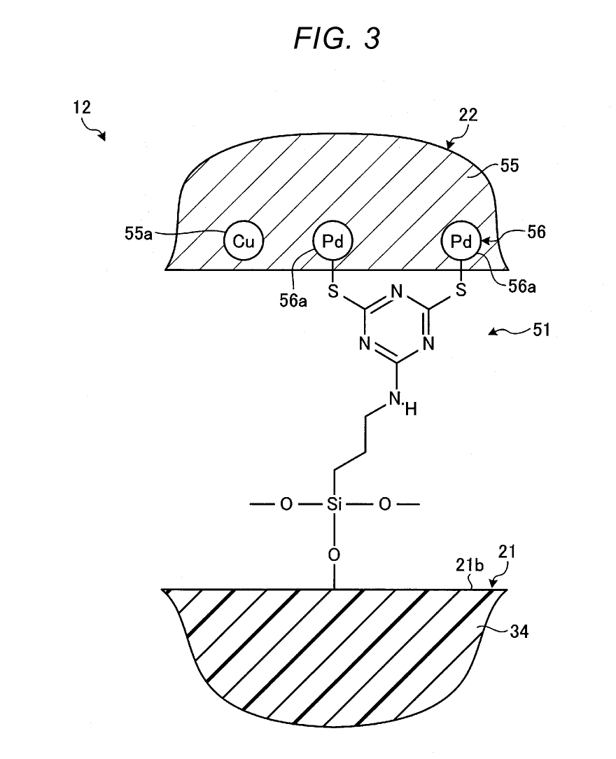

FIG. 3 is an enlarged cross-sectional view of a portion of the semiconductor package 12. As shown in FIG. 3, the semiconductor package 12 further includes a bonding layer 51. The bonding layer 51 is one example of a bonding portion, and may be referred to as an interposed portion, an intermediate portion, or a bonding portion or a layer.

The bonding layer 51 is formed between the electronic component 21 and the shield 22. The bonding layer 51 is chemically bonded to the upper surface 21b and the side surfaces 21c of the electronic component 21, respectively, and is also chemically bonded to the shield 22. To be more specific, the bonding layer 51 results from a chemical reaction of an organic material contained in the upper surface 21b and the side surfaces 21c of the electronic component 21 with the shield 22, so that the bonding layer 51 is bonded to the upper surface 21b and the side surfaces 21c. In other words, the bonding layer 51 results from a chemical reaction of an inorganic material contained in the shield 22 with the material contained in the upper surface 21b and the side surfaces 21c, so that the bonding layer 51 is bonded to the shield 22. That is, the shield 22 is chemically bonded to the upper surface 21b and the side surfaces 21c of the electronic component 21 through the bonding layer 51.

As shown in FIG. 3, the shield 22 has a layer portion 55 and a catalyst portion 56. The layer portion 55 contains layer-forming molecules 55a, which are formed of copper-based (Cu-based) molecules, for example. The layer-forming molecule 55a is one example of a metal-based molecule or a first molecule. The layer portion 55 forms the outer surface 22a of the shield 22 shown in FIG. 2. In other words, the layer-forming molecules 55a exist in the outer surface 22a of the shield 22. The catalyst portion 56 contains catalyst molecules 56a which are palladium-based (Pd-based) molecules, for example. The catalyst molecules 56a are one example of catalyst molecules or second molecules. The palladium-based molecules are one example of an inorganic material.

The bonding layer 51 is chemically bonded to the catalyst molecules 56a, which form the catalyst portion 56 of the shield 22. That is, the catalyst portion 56 of the shield 22 is chemically bonded to the electronic component 21 through the bonding layer 51. The layer-forming molecules 55a precipitate during electroless plating using the catalyst portion 56 chemically bonded to the electronic component 21 as a catalyst, and thereby the layer portion 55 is formed. In other words, the layer portion 55 is chemically bonded to the bonding layer 51 through the catalyst portion 56. The catalyst molecules 56a are not limited to palladium-based molecules, and may be other molecules made of an iron group element, such as iron or nickel, or a platinum group element.

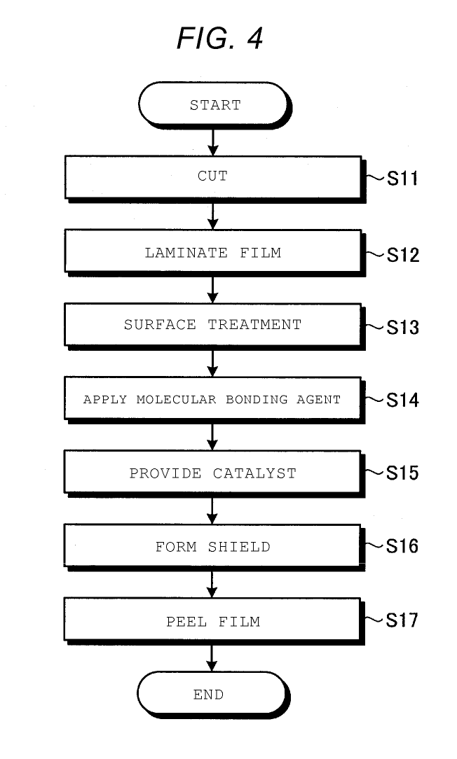

Hereinafter, some steps of a manufacturing method of the semiconductor package 12 are described with reference to FIG. 4 to FIG. 11. The manufacturing method of the semiconductor package 12 is not limited to the method described hereinafter, and the semiconductor package 12 may be manufactured using other methods. FIG. 4 is a flowchart of some steps of the manufacturing method of the semiconductor package 12.

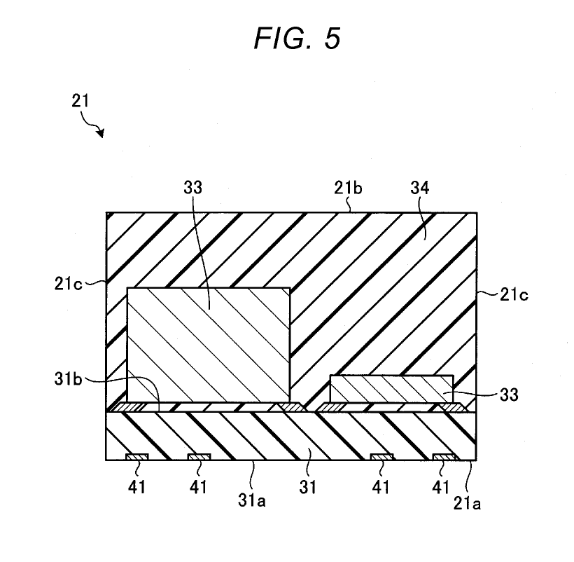

FIG. 5 is a cross-sectional view of the electronic component 21. Firstly, a plurality of electronic components is mounted on one large-sized substrate 31, and the electronic components 33 are covered with the solder resist 34. By fully cutting a large-sized assembled product of the components 21, each having the above-mentioned configuration, using a dicing saw, for example, an individual electronic component 21 shown in FIG. 5 is formed from the integrated product of the components 21 (S11). The configuration of the component (21) is not limited to the above-mentioned configuration, and may have the configuration in which each of the plurality of electronic components 33 is mounted on one of different substrates 31, and the electronic components are covered with the solder resist 34, for example.

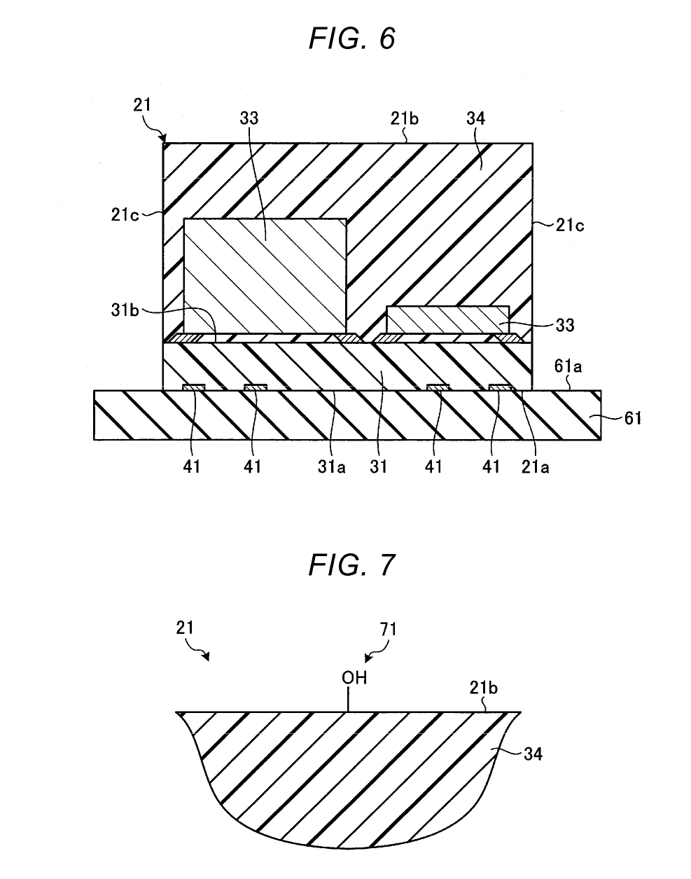

FIG. 6 is a cross-sectional view of the electronic component 21 laminated on a film 61. As shown, as shown in FIG. 6, the electronic component 21 is laminated on the film 61, such that the bottom surface 21a of the electronic component 21 faces the film 61 (S12). The film 61 is a plating resist in a film form. A plating resist in an ink form may be applied to the bottom surface 21a of the electronic component 21 in place of the film 61.

The film 61 covers substantially the whole region of the bottom surface 21a of the electronic component 21. The film 61 may partially cover the bottom surface 21a of the electronic component 21. In this case, the film 61 selectively covers the electrodes 41 arranged on the bottom surface 21a, for example.

The film 61 has an adhesion surface 61a. The bottom surface 21a of the electronic component 21 is adhered to the adhesion surface 61a. The adhesion surface 61a has thermal melting property, and the film 61 becomes removable from the electronic component 21 by being heated. The film 61 is not limited to such a film.

FIG. 7 is a cross-sectional view of a portion of the electronic component 21 to which a surface treatment is performed. As shown, the surface treatment is performed on the electronic component 21 using plasma or corona discharge, for example (S13). According to such a treatment, the upper surface 21b and the side surfaces 21c of the electronic component 21 are cleaned and, at the same time, a hydroxyl group (OH group) 71 is formed on the upper surface 21b and the side surfaces 21c. In FIG. 7, the hydroxyl group 71 is depicted by a chemical formula (molecular formula).

Although FIG. 7 shows only one hydroxyl group 71 for convenience, a plurality of hydroxyl groups 71 is formed on the upper surface 21b and the side surfaces 21c of the electronic component 21. For example, when the hydroxyl groups 71 already exist on the upper surface 21b and the side surfaces 21c, the surface treatment may be omitted. Further, the surface treatment may be performed before the electronic component 21 is laminated on the film 61.

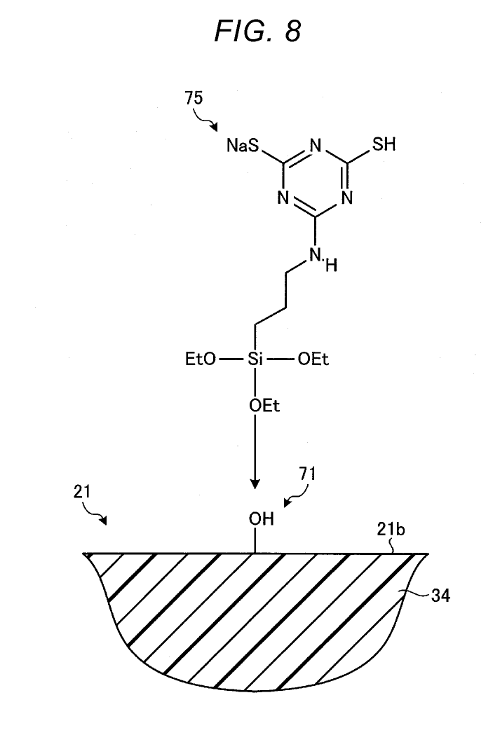

FIG. 8 is a cross-sectional view of a portion of the electronic component 21 and a molecular bonding agent 75. As shown, the molecular bonding agent 75 is applied on the electronic component 21 (S14). The molecular bonding agent 75 may be referred to as a molecular adhering agent. In FIG. 8, the molecular bonding agent 75 is depicted by a chemical formula (structural formula).

The molecular bonding agent 75 is a chemical compound having a functional group which may chemically react with the upper surface 21b and the side surfaces 21c of the electronic component 21, and also with the catalyst portion 56 of the shield 22. The molecular bonding agent 75 is, for example, 6-(3-triethoxysilyl propylamino)-1,3,5-triazine-2,4-dithiol monosodium salt (hereinafter, referred to as TES). The molecular bonding agent 75 is not limited to such a chemical compound.

For example, the electronic component 21 that is laminated on the film 61 and on which the surface treatment is performed is immersed into a chemical liquid containing the molecular bonding agent 75. The chemical liquid is prepared by dissolving the water-soluble molecular bonding agent 75 into a water solvent or an alcoholic solvent, for example.

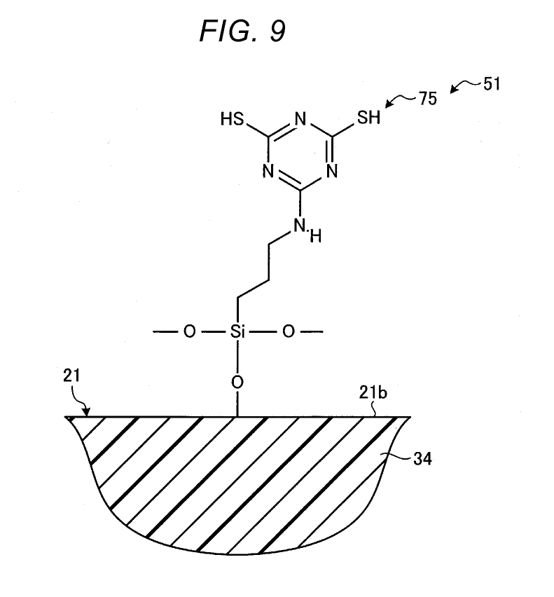

FIG. 9 is a cross-sectional view of a portion of the electronic component 21 to which the molecular bonding agent 75 is chemically bonded. As shown in FIG. 9, the molecular bonding agent 75 in the chemical liquid chemically reacts with the hydroxyl groups 71 formed on the upper surface 21b and the side surfaces 21c of the electronic component 21, so that the molecular bonding agent 75 is chemically bonded to the upper surface 21b and the side surfaces 21c. According to such a reaction, the bonding layer 51 is formed.

For example, TES, which is the molecular bonding agent 75, is chemically bonded to the upper surface 21b and the side surfaces 21c of the electronic component 21 so that a dithiol triazine group, which is a functional group capable of chemically reacting with the catalyst portion 56 of the shield 22, is formed on a front surface of the bonding layer 51 (a portion on a side opposite to the electronic component 21). The molecular bonding agent 75 is not limited to TES.

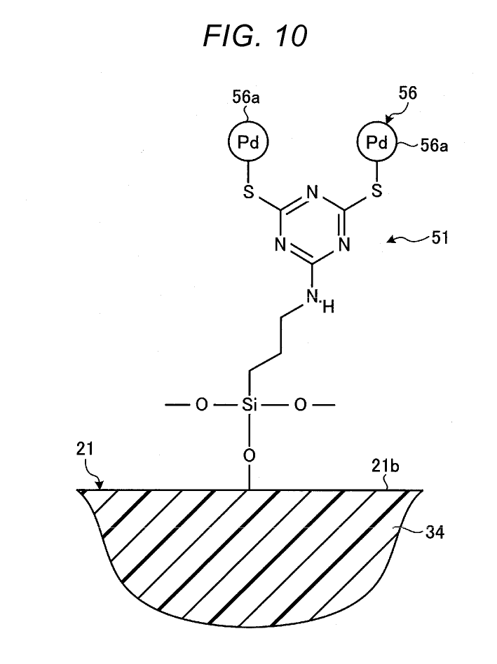

FIG. 10 is a cross-sectional view of a portion of the electronic component 21 in which the catalyst molecules 56a are chemically bonded to the molecular bonding agent 75. As shown, the catalyst molecules 56a connected to the bonding layer 51, which is formed on the upper surface 21b and the side surfaces 21c of the electronic component 21 (S15).

For example, palladium-based molecules, which serve as the catalyst molecules 56am chemically react with dithiol triazine groups formed on the surface of the bonding layer 51, so that the palladium-based molecules are chemically bonded to the bonding layer 51. In this manner, the catalyst molecules 56a chemically bonded to the bonding layer 51 become the catalyst portion 56. According to the formation of the catalyst portion 56, a surface of the electronic component 21 covered with the bonding layer 51 is metalized.

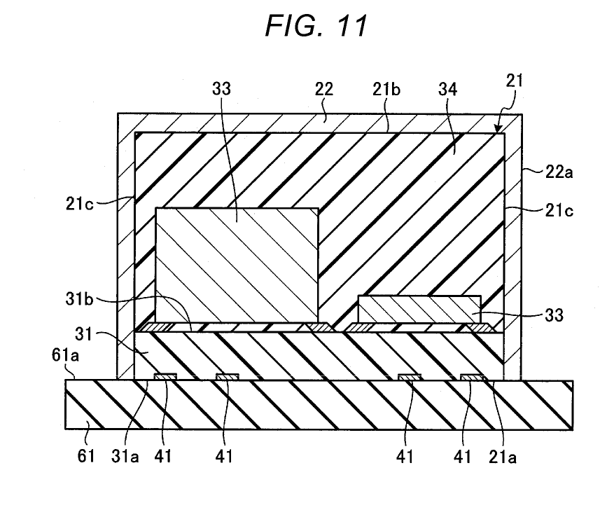

FIG. 11 is a cross-sectional view of the electronic component 21 on which the shield 22 is formed. As shown, by forming the layer portion 55 shown in FIG. 3 on the electronic component 21, the shield 22 is formed (S16). The layer portion 55 of the shield 22 can be formed by electroless plating as described above. Copper-based molecules, which are layer-forming molecules 55a, precipitate on the surface of the catalyst portion 56 using the catalyst portion 56 as a catalyst. The layer portion 55 is formed by precipitation of copper-based molecules, whereby, as shown in FIG. 11, the shield 22 which covers the upper surface 21b and the side surfaces 21c of the electronic component 21 is formed.

The layer portion 55 precipitates on the catalyst portion 56, which is chemically bonded to the upper surface 21b and the side surfaces 21c of the electronic component 21 through the bonding layer 51. Accordingly, the shield 22 having the layer portion 55 and the catalyst portion 56 is chemically bonded to the upper surface 21b and the side surfaces 21c of the electronic component 21 through the bonding layer 51.

The method of forming the shield 22 is not limited to the above-mentioned method, and the shield 22 may be formed by other methods, such as sputtering. Sputtering can be performed on the electronic component 21 when the bonding layer 51 is formed on the upper surface 21b and the side surfaces 21c of the electronic component 21. Metal molecules deposited on the surface of the bonding layer 51 by sputtering are chemically bonded to the bonding layer 51. In this manner, the shield 22 formed by sputtering is also chemically bonded to the upper surface 21b and the side surfaces 21c of the electronic component 21 by the bonding layer 51.

Next, the film 61 is peeled off from the bottom surface 21a of the electronic component 21 (S17). By peeling off the film 61, the electrodes 41 mounted on the bottom surface 21a are exposed. By mounting the terminals 32 on the electrodes 41 respectively, the semiconductor package 12 shown in FIG. 2 is formed.

In the electronic device 1 according to the embodiment described above, the shield 22, which covers at least a portion of the electronic component 21, is chemically bonded to the upper surface 21b and the side surfaces 21c of the electronic component 21. According to such a configuration, the electronic component 21 covered by the shield 22 may be miniaturized as described below.

In the related art, in forming a shield by plating, an outer surface of a component may be roughened to increase an adhesive force between the shield and the electronic component. To securely cover the electronic component with a solder resist having the rough surface, the solder resist, which forms an outer surface of the component, may have to be formed with a large thickness.

In contrast, in the electronic device 1 according to this embodiment, the shield 22 is chemically bonded, for example, by hydrogen bonding, covalent bonding, and ionic bonding, to the electronic component 21. Since an adhesive force (an adhesive strength, a peeling strength) according to chemical bonding is sufficiently larger than an adhesive force by a Van der Waals' force which acts between an adhesive agent and an object to be adhered, it is unnecessary to roughen the upper surface 21b and the side surfaces 21c of the electronic component 21. Accordingly, the solder resist 34 of the electronic component 21 may have a smaller thickness compared to the case where the upper surface 21b and the side surfaces 21c of the electronic component 21 are roughened. As a result, the electronic component 21 may be miniaturized. Further, since, in the electronic device 1 according to this embodiment, an adhesive force between the shield 22 and the electronic component 21 is sufficiently large, the reliability of the semiconductor package 12 maybe improved. In addition to such advantageous effects, when the electronic device 1 according to this embodiment is manufactured, a thickness of the shield 22 may be thinner compared to the case where the solder resist 34 of the electronic component 21 is roughened, and hence a time for forming the shield 22 may be shortened.

Further, in the related art, when an outer surface of a component is roughened, a surface on which electrodes of the component are arranged can be protected by a resist (film). In this case, an alkaline chemical liquid, which is used for roughing the outer surface of the component, may intrude into an adhering portion between the resist and the electronic component and corrode the adhering portion. When the adhering portion is corroded by the chemical liquid, plating may be formed also on a surface on which the electrodes are arranged, and as a result a production yield of the electronic components may be lowered.

In contrast, in the electronic device 1 according to this embodiment, as described above, it is unnecessary to roughen the upper surface 21b and the side surfaces 21c of the electronic component 21. Accordingly, it is possible to prevent the situation where the bonding portion between the electronic component 21 and the film 61 is corroded by a chemical liquid and a production yield of the electronic components 21 is lowered. Further, the film 61 does not need to have resistance to a chemical liquid for roughening (for example, alkali resistance), and hence the number of materials that can be used for the film 61 is increased.

The larger the electronic component becomes in size, the more the electronic component is likely to be deformed due to strains or thermal expansion. When the component is deformed, a chemical liquid for roughening is more likely to infiltrate into the bonding portion between the component and the resist.

In the electronic device 1 according to this embodiment, as described above, it is unnecessary to roughen the upper surface 21b and the side surfaces 21c of the electronic component 21. Accordingly, compared to a case where the solder resist 34 is roughened, the size of the electronic component 21 may be large.

The bonding layer 51, which is chemically bonded to the upper surface 21b and the side surfaces 21c of the electronic component 21 and to the shield 22, is formed between the electronic component 21 and the shield 22. According to such a configuration, even when the shield 22 and the upper surface 21b and the side surfaces 21c of the electronic component 21 are formed using the different kinds of materials, the shield 22 may be chemically bonded to the upper surface 21b and the side surfaces 21c of the electronic component 21 through the bonding layer 51.

The bonding layer 51 is chemically bonded to the catalyst molecules 56a of the shield 22. As the catalyst molecules 56a function as a catalyst, the layer molecules 55a are formed on the upper surface 21b and the side surfaces 21c of the electronic component 21 by electroless plating through the bonding layer 51. Through this process, the shield 22 which covers at least a portion of the electronic component 21 may be easily formed. Further, the shield 22 maybe easily formed by electroless plating, and hence, compared to the case where the shield 22 is formed by sputtering, a manufacturing cost of the electronic component 21 may be reduced. Further, compared to the case where the shield 22 is formed by sputtering, a thickness of the bonding layer 51 may become more uniform.

The bonding layer 51 contains the molecular bonding agent 75 having a functional group capable of chemically reacting with the upper surface 21b and the side surfaces 21c of the electronic component 21 and also chemically reacting with the shield 22. With the use of such a molecular bonding agent 75, the upper surface 21b and the side surfaces 21c of the electronic component 21 may be converted into one kind of functional group. Even when the shield 22 and the upper surface 21b and the side surfaces 21c of the electronic component 21 are respectively formed using different kinds of materials, the shield 22 may be chemically bonded to the upper surface 21b and the side surfaces 21c of the electronic component 21 through the bonding layer 51.

The shield 22 covers the upper surface 21b and the side surfaces 21c of the outer surface of the electronic component 21 except for the bottom surface 21a on which the electrodes 41 are arranged. According to such a configuration, it is possible to suppress short-circuit of the electrodes 41 by the shield 22.

The electronic component 21 includes the electronic components 33, which generate an electromagnetic wave, and the substrate 31, and the solder resist 34, which cover the electronic components 33. The shield 22 covers at least a portion of the upper surface 21b and the side surfaces 21c of the electronic component 21 where the substrate 31 and the solder resist 34 are formed. According to such a configuration, electromagnetic waves which the electronic components 33 generate are shielded by the shield 22, and hence the radiation of electromagnetic waves by the electronic device 1 may be suppressed.

According to at least one of the embodiments described heretofore, the conductive portion is chemically bonded to the outer surface of the electronic component and covers at least the portion of the outer surface of the electronic component. According to such a configuration, the electronic component covered by the conductive portion may be miniaturized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device module, comprising:
an electronic unit;
a sealing layer covering the electronic unit and containing organic molecules;
a shield layer covering the sealing layer and containing inorganic elements on an inner surface thereof; and
a bonding layer formed between the sealing layer and the shield layer, and containing molecules that are chemically bonded with the organic molecules of the sealing layer and the inorganic elements of the shield layer.

2. The electronic device module according to claim 1, wherein the shield layer contains catalyst elements for metal plating as the inorganic elements.

3. The electronic device module according to claim 2, wherein the catalyst elements include at least one of palladium, iron, nickel, and platinum.

4. The electronic device module according to claim 2, wherein the shield layer includes metal elements that are chemically bonded with the catalyst elements.

5. The electronic device module according to claim 4, wherein the metal elements include copper.

6. The electronic device module according to claim 1, wherein
the sealing layer includes a top surface and side surfaces, and
the bonding layer is formed on the top surface and the side surfaces of the sealing layer.

7. The electronic device module according to claim 1, wherein
an electronic unit is configured to radiate an electromagnetic wave, and
the shield layer shields the electromagnetic wave radiated from the electronic unit.

8. A method for manufacturing an electronic device module, comprising:
preparing a structure including an electronic unit and a sealing layer covering the electronic unit and containing organic molecules;
applying a bonding material on the sealing layer, the bonding material containing molecules that are chemically bondable with the organic molecules of the sealing layer; and
forming a shield layer on the bonding material, the shield layer containing inorganic elements on an inner surface thereof that are chemically bonded with the molecules of the bonding material.

9. The method according to claim 8, further comprising:
prior to applying the bonding material, forming hydroxyl groups on the outer surface of the sealing layer.

10. The method according to claim 8, wherein
a dithiol triazine group is generated when the molecules of the bonding material are chemically bonded with the organic molecules of the sealing layer.

11. The method according to claim 8, wherein forming the shield layer includes
forming, on the bonding material, catalyst elements for metal plating that are chemically bondable with the molecules of the bonding material, as the inorganic elements, and
forming, on the catalyst elements, metal elements that are chemically bondable with the catalyst elements.

12. The method according to claim 11, wherein the catalyst elements include at least one of palladium, iron, nickel, and platinum.

13. The method according to claim 11, wherein the metal elements include copper.

14. The method according to claim 11, wherein
the metal elements are formed by an electroless plating using the catalyst elements.

15. The method according to claim 8, wherein
the sealing layer includes a top surface and side surfaces, and
the bonding layer is formed on the top surface and the side surfaces of the sealing layer.

16. The method according to claim 8, wherein
the electronic unit is configured to radiate an electromagnetic wave, and
the shield layer shields the electromagnetic wave radiated from the electronic unit.

17. A method for shielding an electromagnetic wave radiated from an electronic unit, comprising:
covering an electronic unit with a sealing layer containing organic molecules;
applying a bonding material on the sealing layer, the bonding material containing molecules that are chemically bondable with the organic molecules of the sealing layer; and
forming a shield layer on the bonding material, the shield layer containing inorganic elements on an inner surface thereof that are chemically bonded with the molecules of the bonding material.

18. The method according to claim 17, further comprising:
prior to applying the bonding material, forming hydroxyl groups on the outer surface of the sealing layer.

19. The method according to claim 17, wherein the forming of the shield layer includes
forming, on the bonding material, catalyst elements for metal plating that are chemically bondable with the molecules of the bonding material, as the inorganic elements, and
forming, on the catalyst elements, metal elements that are chemically bondable with the catalyst elements.

20. The method according to claim 19, wherein
the metal elements are formed by an electroless plating using the catalyst elements.
